(19) United States
(12) Patent Application Publication
(10) Pub. No.: US 2009/0262570 A1
(43) Pub. Date: Oct. 22, 2009

(54) Giant magnetoresistance (GMR) memory device

(75) Inventor: Ronald Potok, Austin, TX (US)

Correspondence Address: HAMILTON & TERRILE, LLP - AMD, P.O. BOX 203518, AUSTIN, TX, 78720, US

(73) Assignee: Advanced Micro Devices, Inc.

(21) Appl. No.: 12/148,020

(22) Filed: Apr. 16, 2008

(51) Int. Cl. G11C 11/02

(52) U.S. Cl. 365/158

(57) ABSTRACT

The present magnetic memory device includes a pinned ferromagnetic layer, and a switchable ferromagnetic layer, the memory device being programmable to have a first programmed state wherein the resistance of the device is at a first level, a second programmed state wherein the resistance of the device is at a second level greater than the first level, and a third programmed state wherein the resistance of the device is at a third level greater than the second level.

### BACKGROUND OF THE INVENTION

1. Field of the Invention

This invention relates generally to memory devices, and more particularly, to giant magnetoresistance (GMR) memory devices.

2. Discussion of the Related Art

FIG. 1 illustrates a conventional giant magnetoresistance (GMR) device 20. As is well known, the GMR device 20 includes, in successive layers, an anti ferromagnetic pinning layer 22, a ferromagnetic pinned layer 24, a non magnetic conductive layer 26, a ferromagnetic switchable layer 28, and another non magnetic conductive layer 30.

The device 20 is capable of two resistance states, a first, low resistance state wherein the direction of magnetization 32 of the switchable layer 28 is aligned with the direction of magnetization 34 of the pinned layer 24 (FIGS. I and 2), and a second, high resistance state, wherein the direction of magnetization 32 of the switchable layer 28 is anti-aligned with the direction of magnetization 34 of the pinned layer 24 (FIGS. 3 and 4).

The device 20 is switchable between states by applying an appropriate magnetic or electric field thereto.

FIG. 5 shows the read step of the device 20 with that device 20 in its low-resistance state. As such, a read voltage of a selected magnitude is applied across the device 20, to provide a current through the device 20. With the device 20 in its relatively low resistance state, the current 36 through the device 20 will be detected as relatively high. On the other hand, with reference to FIG. 6, with the device 20 in its high-resistance state, and with that voltage again applied across the device 20, the current 38 through the device 20 will be relatively low, and can be detected as such to determine that the device 20 is in its high-resistance state.

It will be understood that it is desirable to reduce the size of a GMR memory device 20 to increase storage per unit area and hence decrease cost per memory bit. However, as magnetic device size decreases, certain fundamental limits come into play, such as superparamagnetic transitions, which lead to reduced reliability of extremely scaled magnetic storage media. That is to say, there is a physical limit to the size of a magnet in the direction of magnetization, i.e., a certain relatively large number of magnetic atoms are needed in order to form a permanent magnet. Consequently, the degree to which the dimension A in FIG. 2 can be reduced is limited by these constraints. In a conventional approach, in order to reduce device size as much as practicable, the switchable layer 28 is provided in an elliptical shape as shown in FIG. 2, with the dimension A being sufficient to ensure that a permanent magnet state can be achieved therein. This results in the device 20 being capable of adopting two distinct, stable states as described above.

Since the scaling of the device 20 is limited as described above, it would be advantageous if the device 20 could hold more than two states of resistance, so that information storage can increase without decreasing the physical size of the device 20.

Therefore, what is needed is a GMR device 20 which is capable of adopting more than two resistance states.

### SUMMARY OF THE INVENTION

Broadly stated, the present magnetic memory device comprises a pinned ferromagnetic layer, and a switchable ferromagnetic layer, the memory device being programmable to have a first programmed state wherein the resistance of the device is at a first level, a second programmed state wherein the resistance of the device is at a second level greater than the first level, and a third programmed state wherein the resistance of the device is at a third level greater than the second level.

The present invention is better understood upon consideration of the detailed description below, in conjunction with the accompanying drawings. As will become readily apparent to those skilled in the art from the following description, there is shown and described an embodiment of this invention simply by way of the illustration of the best mode to carry out the invention. As will be realized, the invention is capable of other embodiments and its several details are capable of modifications and various obvious aspects, all without departing from the scope of the invention. Accordingly, the drawings and detailed description will be regarded as illustrative in nature and not as restrictive.

### BRIEF DESCRIPTION OF THE DRAWINGS

The novel features believed characteristic of the invention are set forth in the appended claims. The invention itself, however, as well as said preferred mode of use, and further objects and advantages thereof, will best be understood by reference to the following detailed description of an illustrative embodiment when read in conjunction with the accompanying drawings, wherein:

FIG. 1-6 illustrate a prior art approach in the art of a giant magnetoresistance memory device; and

FIGS. 7-18 illustrate the present approach for a giant magnetoresistance memory device.

### DETAILED DESCRIPTION

Reference is now made in detail to a specific embodiment of the present invention which illustrates the best mode presently contemplated by the inventors for practicing the invention.

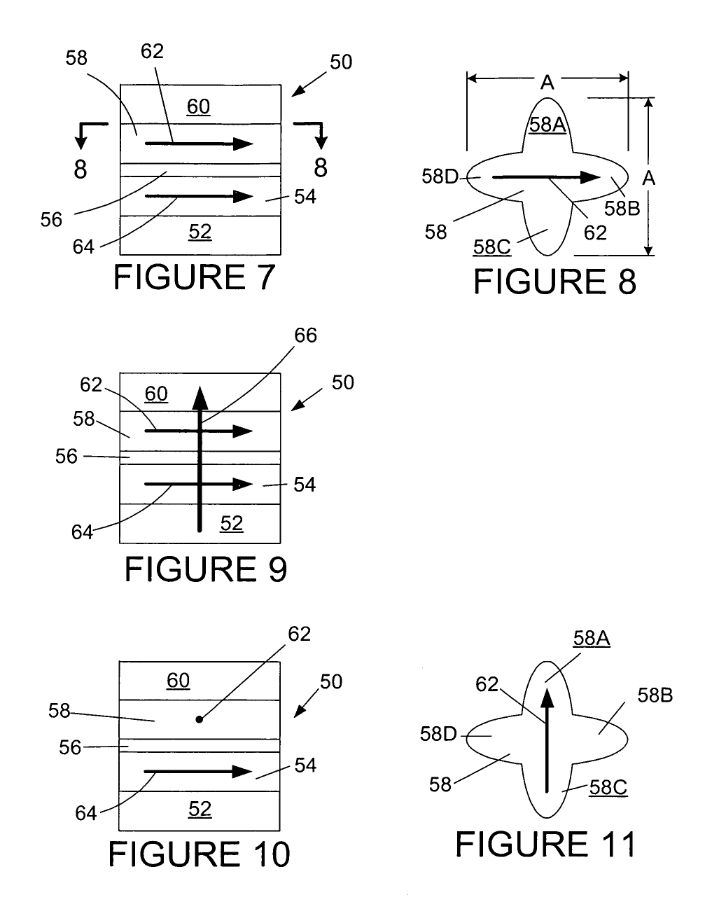

As in the prior art, the present GMR device 50 includes, in successive layers, an anti ferromagnetic pinning layer 52, a ferromagnetic pinned layer 54, a non magnetic conductive layer 56, a ferromagnetic switchable layer 58, and a non magnetic conductive layer 60 (FIG. 7). However, instead of the ferromagnetic switchable layer 58 having an elliptical shape, the layer 58 is generally cross-shaped in configuration (FIG. 8), having first, second, third and fourth extending lobes 58A, 58B, 58C, 58D, with the first and third lobes 58A, 58C extending in opposite directions, and the second and fourth lobes 58B, 58D extending in opposite directions. The dimension across the lobes 58B, 58D is shown as A, similar to the prior art, while the dimension across the lobes 58A, 58C is also shown as A, so that the switchable layer 58 is capable of holding more that two stable states of direction of magnetization as will be described.

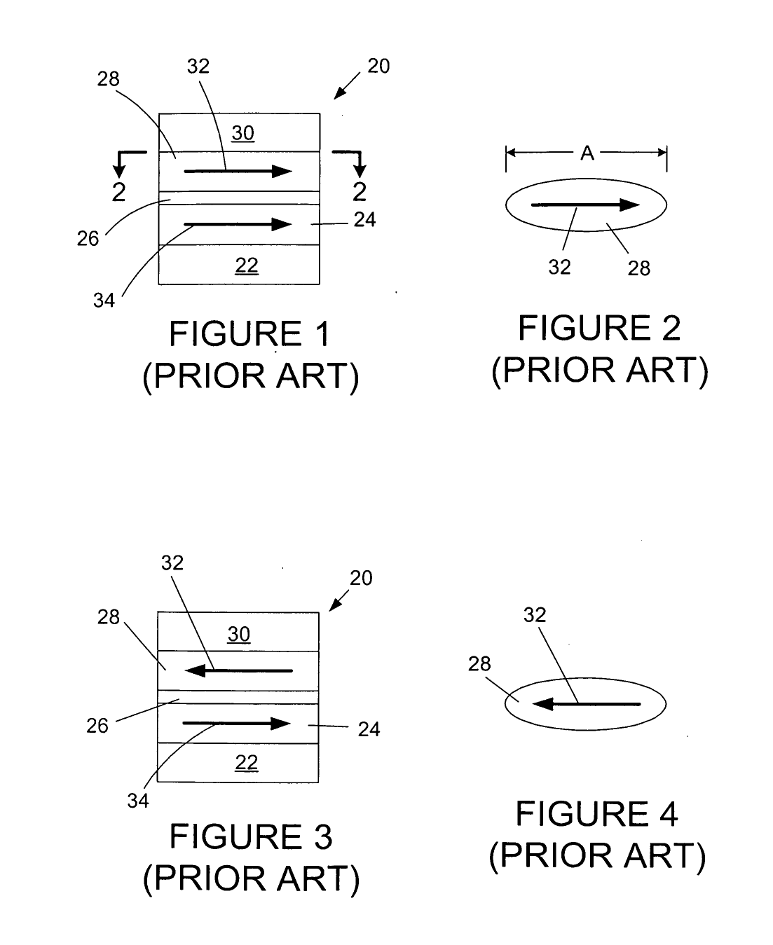

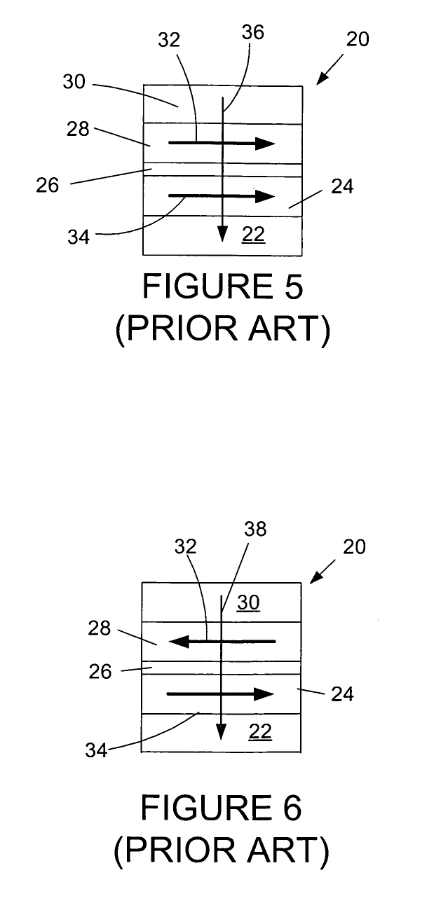

In FIGS. 7 and 8, the device 50 is shown in its low-resistance state, with the directions of magnetization 62, 64 of the switchable layer 58 and pinned layer 54 aligned, similar to FIGS. 1 and 2 of the prior art. As such, as shown in FIG. 8, the direction of magnetization 60 of the switchable layer 58 is from the lobe 58D to the lobe 58B.

In order to write each of the multiple states, a spin transfer torque can be applied to the device 50 by applying a large write current 66 from the pinned layer 54 through the switchable layer 58. The direction of magnetization 62 of the switchable layer 58 then precesses both in and out of the plane thereof, and the amount of time, magnitude and direction of current 66 applied will determine the final, stable storage state of the device 50.

With reference to FIG. 9, the device 50 can be made to switch to a second, higher resistance programmed state depending on the current 66 pulse width and/or height applied through the device 50 as described above

FIGS. 10 and 11 show the device 50 in the second, higher resistance state with the direction of magnetization 62 of the switchable layer 58 being at 90° to the direction of magnetization 64 of the pinned layer 54, i.e., neither aligned nor non-aligned with the direction of magnetization 64 of the pinned layer 54. This results in a second, higher resistance state of the device 50 than as shown in FIGS. 7 and 8. In this situation, the direction of magnetization of the switchable layer is from the lobe 58C to the lobe 58A.

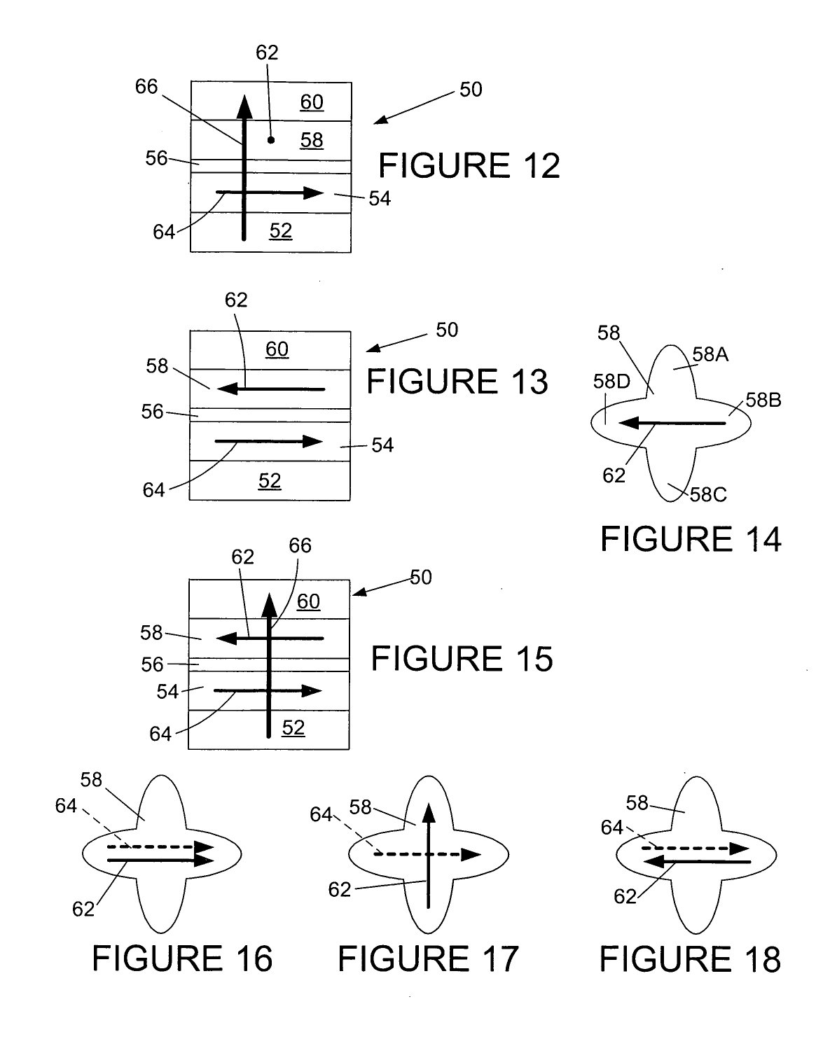

With reference to FIG. 12, the device 50 can be made to switch to a third, even higher resistance programmed state depending on the current 66 pulse width and/or height applied through the device 50 as described above

FIGS. 13 and 14 show the device 50 in a third resistance state, with resistance higher than that in the approach of FIGS. 10 and 1 1, and indeed similar to that shown in FIGS. 3 and 4 in the prior art. As such, the direction of magnetization 62 of the switchable layer 58 and the direction of magnetization 64 of the pinned layer 54 are anti-aligned, resulting in a resistance state higher than that shown in the approach of FIGS. 9 or 10. In this situation, the direction of magnetization 62 of the switchable layer 58 is from the lobe 58B to the lobe 58D.

With reference to FIG. 15, the device can be made to switch to its original resistance programmed state (FIGS. 7 and 8), depending on the current pulse 66 width and/or height applied through the device 50 as described above

The three states are shown in FIGS. 16, 17 and 18 which overlay the direction of magnetization of the switchable layer with the direction of magnetization of the pinned layer (FIG. 16, aligned, FIG. 17, neither aligned nor antialigned, i.e., at 90°, FIG. 15, anitaligned).

The three different states of the memory device 50 can be read as described in the prior art.

The capability of the memory device 50 to hold more than two resistive states greatly enhances the amount of storage capability for an array of devices, without having to decrease the physical device size.

Besides using shape anisotropy for the switchable layer 58 as shown and described, one could also use magnetic anisotropy to create or reinforce the states on magnetism.

The foregoing description of the embodiment of the invention has been presented for purposes of illustration and description. It is not intended to be exhaustive or to limit the invention to the precise form disclosed. Other modifications or variations are possible in light of the above teachings.

The embodiment was chosen and described to provide the best illustration of the principles of the invention and its practical application to thereby enable one of ordinary skill of the art to utilize the invention in various embodiments and with various modifications as are suited to the particular use contemplated. All such modifications and variations are within the scope of the invention as determined by the appended claims when interpreted in accordance with the breadth to which they are fairly, legally and equitably entitled.

What is claimed is:

1. A magnetic memory device comprising:
a pinned ferromagnetic layer;
a switchable ferromagnetic layer;
the memory device being programmable to have a first programmed state wherein the resistance of the device is at a first level, a second programmed state wherein the resistance of the device is at a second level greater than the first level, and a third programmed state wherein the resistance of the device is at a third level greater than the second level.

2. The memory device of claim 1 wherein in the first programmed state the direction of magnetization of the pinned ferromagnetic layer and the direction of magnetization of the switchable ferromagnetic layer are aligned, in the third programmed state the direction of magnetization of the pinned ferromagnetic layer and the direction of magnetization of the switchable ferromagnetic layer are antialigned, and in the second programmed state the direction of magnetization of the pinned ferromagnetic layer and the direction of magnetization of the switchable ferromagnetic layer are neither aligned nor antialigned.

3. The memory device of claim 2 wherein in the second programmed state the direction of magnetization of the pinned ferromagnetic layer and the direction of magnetization of the switchable ferromagnetic layer are at 90° to each other.

4. The memory device of claim 1 wherein the memory device is a giant magnetoresistance (GMR) memory device.

5. A magnetic memory device comprising:
a pinned ferromagnetic layer; and
a switchable ferromagnetic layer;
the switchable ferromagnetic layer being capable of at least three directions of magnetization.

6. The memory device of claim 5 wherein the first and third directions are opposite each other, and the second direction is at an angle relative to the first and third directions.

7. The memory device of claim 6 wherein the second direction is 90° from the first and third directions.

8. The memory device of claim 5 wherein the memory device is a giant magnetoresistance (GMR) memory device.

9. A magnetic memory device comprising:
a pinned ferromagnetic layer; and
a switchable ferromagnetic layer;
the switchable ferromagnetic layer having more than two extending lobes.

10. The memory device of claim 9 wherein the switchable ferromagnetic layer has first, second, third and fourth extending lobes.

11. The memory device of claim 10 wherein a first pair of lobes extend in opposite directions, and a second pair of lobes extend in opposite directions.

12. The memory device of claim 10 wherein the switchable ferromagnetic layer is generally cross-shaped in configuration.

13. The memory device of claim 9 wherein the memory device is a giant magnetoresistance (GMR) memory device.
